(19) United States
(12) Patent Application Publication
(10) Pub. No.: US 2008/0266805 A1
(43) Pub. Date: Oct. 30, 2008

(54) Carrier For Electrical Components With Soldered-On Cooling Body

(75) Inventor: Heino Martin Burema, Mierlo (NL)

Correspondence Address: BANNER & WITCOFF, LTD., 1100 13th STREET, N.W., SUITE 1200, WASHINGTON, DC, 20005-4051, US

(73) Assignee: ELECTRISCHE APPARATENFABRIEK CAPAX B.V., Eindhoven (NL)

(21) Appl. No.: 11/791,935

(22) PCT Filed: Nov. 29, 2005
(86) PCT No.: PCT/NL2005/050054

§ 371 Date: Apr. 10, 2008

(30) Foreign Application Priority Data
Dec. 1, 2004 (NL) 1027632

(51) Int. Cl. H05K 7/20; B21D 53/02

(52) U.S. Cl. 361/707; 29/890.03

(57) ABSTRACT

The invention relates to an assembly of a carrier for electrical components that are arranged for producing more heat than can be dissipated via natural cooling at least under certain operating conditions and a cooling body mechanically and thermally connected thereto, whereby the carrier is provided with a metal part that is connected to the cooling body by means of a metallic connection. Mounting a metal part on the carrier makes it possible to form a metallic connection between the metal part and the metal cooling body. The invention also relates to a method for assembling an assembly of a carrier for heat-producing electrical components and a cooling body mechanically and thermally connected thereto, whereby the components are initially mounted on the carrier and a metal part of the carrier is then connected to the cooling body by means of a metallic connection.

The present invention relates to a carrier for electrical components, whereby the heat generated by the components has to be dissipated. More particularly, the invention relates to an assembly of a carrier for electrical components that are arranged to generate more heat than can be dissipated via natural cooling at least under certain operating conditions and a cooling body thermally connected thereto.

To dissipate the heat generated by electrical components such as resistors and semi-conductors, the use of cooling bodies thermally connected to the housing of the components has been known for a long time. The thermal connection required in this respect dictates the position of the cooling bodies, which means that they cannot be applied in all situations.

The use of carriers made of ceramic material having a low thermal resistance makes it possible to dissipate the heat generated by the components via the carrier. This provides greater freedom with respect to positioning the cooling bodies. According to the prior art, positioning the cooling body tightly against the carrier is known. The unavoidable layer of air between carrier and cooling body increases thermal resistance. This can partially be resolved by applying a thermally conductive paste between both parts. However, only a moderate improvement is hereby achieved.

The object of the invention is to provide such an assembly, whereby the thermal resistance between the heat-generating components and the cooling body is as low as possible, while heat continues to be transferred through the carrier.

This object is achieved in that the carrier is provided with a metal part that is connected to the cooling body by means of a metallic connection.

Mounting a metal part on the carrier makes it possible to form a metallic connection between the metal part and the metal cooling body.

A metallic connection in this respect is understood to be a connection such as a connection formed by welding or soldering, or a connection formed by an adhesive having a high content of metal particles.

The metallic connection between the metal part of the carrier and the cooling body is preferably formed by a soldered connection. This means of connection provides the fewest problems in terms of technology, because use is already made of soldering when attaching the components to the carrier. However it is also possible to use welds, for example laser welds, to form this connection.

Using a soldered connection to form the connection between cooling body and carrier and connecting the components to the carrier by means of a soldered connection is preferable in that the melting temperature of the soldered connection between the components and the carrier is higher than the melting temperature of the soldered connection between the carrier and the cooling body. This prevents the soldered connection between the carrier and the components from coming apart when soldering the cooling body, which could in turn displace the components.

According to an attractive preferred embodiment, the carrier is produced out of ceramic material. Ceramic material generally has a high electrical resistance and high thermal conductivity, which is of great importance in the present invention because the thermal current has to pass through the carrier.

A profound connection between the carrier and the metal part is required for the invention; to this end, use is preferably made of screen-printing a thin metal layer onto the carrier, preferably in the same way in which the metal tracks for the components are mounted on the carrier. Other methods for applying the layer are not however excluded.

To make the thermal path as short as possible, the metal part of the carrier is preferably mounted on the opposite side of the carrier that is supporting the components, directly opposite the components.

The cooling body is preferably in sheet form. The ratio between volume and surface area of a sheet is indeed attractive for dissipating heat. Furthermore, a sheet is easy to achieve from a production engineering perspective.

To make the cooling surface area as large as possible, the surface area of the sheet is preferably greater than the surface area of the carrier.

The circuit is usually mounted in a casing. The options for transferring heat are restricted within the casing, so it is attractive for at least part of the cooling surface to be positioned outside the casing.

Yet another preferred embodiment provides the feature that the thickness of the cooling body is at least equal to the thickness of the carrier. This embodiment is particularly applicable in situations in which the components positioned on the carrier are subjected to a short-term thermal load. This thermal load can be greater than the heat dissipation capacity of the cooling body. This will not however lead to problems if the heat storage capacity of the cooling body is sufficiently large to absorb the heat produced during such a period of thermal loading. This heat can then be stored in the cooling body and later dissipated during a period in which less heat is generated. This operating method can only be applied if the heat capacity of the cooling body is sufficiently large, as can be achieved by specifying a given thickness for the cooling sheet With the applications provided by the applicant, this turns out to result in the thickness of the cooling sheet being at least equal to the thickness of the carrier.

According to yet another embodiment, the melting temperature of the soldered connection between the carrier and the cooling body is lower than the maximum temperature of the carrier occurring in short-term operation.

In addition to the feature described above, this feature is necessary to increase the thermal storage capacity of the assembly. If the temperature of the carrier exceeds the melting temperature of the soldered connection, the solder will melt and thus absorb thermal energy. If the temperature then drops, the solder will resolidify and again transfer its heat. It should however be ensured that the carrier and the cooling sheet remain in position, so that the soldered connection can again be established when the temperature drops.

The invention relates not only to the assembly described above, but also to the method for assembling the said assembly, namely a method for assembling an assembly of a carrier for electrical components, at least one of which is arranged for generating more heat than can be dissipated via natural cooling at least under certain operating conditions, and a cooling body mechanically and thermally connected thereto, whereby the components are initially mounted on the carrier and a metal part of the carrier is then connected to the cooling body by means of a metallic connection.

From a production engineering perspective, it turns out to be attractive to initially position the components on the carrier and only then to mount the cooling sheets.

These advantages are further apparent if the components are initially connected to the carrier by means of a soldered connection having a first melting point and then the cooling body is connected to the metallic part of the carrier by means of a soldered connection, whereby the melting point of the second soldered connection is lower than that of the first soldered connection.

As stated above, such a carrier is usually mounted in a casing, for example a switch casing. It is thus usually not possible to incorporate the completed assembly of carrier in the casing, including components and the cooling body once they have been assembled. It is therefore attractive, once the components have been soldered, to position the carrier in a housing, to then mount the cooling body at least partially in the housing and finally to secure the soldered connection between the cooling body and the metallic part of the carrier, This is an unusual sequence in that the carrier and the cooling body have to be soldered in order to interconnect. Consideration must therefore be given to selecting a material for the casing that is resistant to the temperatures that occur during the soldering process.

In the soldering process, in particular, but not exclusively if it has to be carried out inside the housing, there is a limited accessibility of the surfaces to be soldered. It is therefore attractive to carry out a ‘reflow’ soldering process, whereby the solder is applied to the surfaces to be soldered before the soldering process is carried out. The soldering then takes place by heating the elements to be soldered to the melting temperature.

An area of application involving small carriers on which components are placed generating considerable heat is the power control of energy converters, such as electromotors and heating elements.

Particularly with electromotors, the power controller usually has the function of controlling speed or torque.

The switching semi-conductor elements, such as FETs, triacs or thyristors, are thus subjected to a heavy load, so the advantages of the invention are particularly apparent in such applications.

Such applications can be seen with devices driven by electromotors, such as electrical hand tools, as well as with vacuum cleaners and kitchen equipment.

As described above, the invention is also applicable in situations in which electromotors are subjected to short-term loads. This makes the invention particularly suitable for use with drilling and screwing machines.

Further features of the present invention will emerge from the accompanying drawings, in which the following are shown:

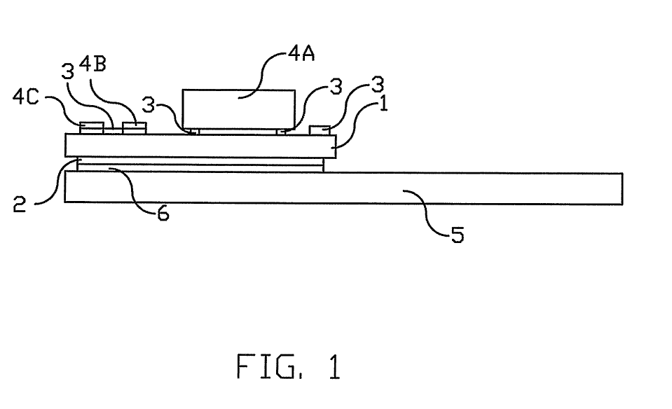

FIG. 1: A cross-section view of an assembly according to the invention; and

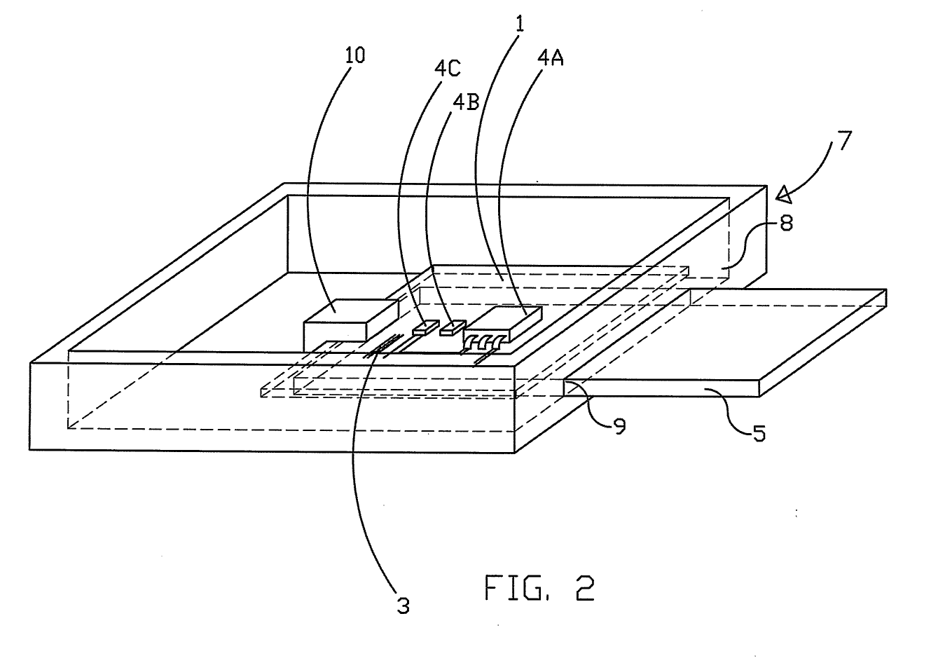

FIG. 2: A schematic three-dimensional view of an assembly according to the invention, mounted in a housing.

FIG. 1 shows a ceramic carrier 1 that is provided with a metal layer 2 on its underside. This metal layer 2 is preferably applied by means of screen-printing. A metal track pattern 3 is mounted on the upper side of the ceramic carrier 1. A number of electrical components 4A, 4B, 4C are attached to this track pattern 3 by means of soldering. The component 4A is hereby a power component that produces considerable heat under certain operating conditions to be dissipated via a cooling body. To this end, a metal, preferably copper, cooling sheet 5 is mounted on the underside of the ceramic carrier 1. This cooling sheet 5 is metallically connected to the metal layer 2 of the ceramic carrier 1 by means of a soldered connection 6. The sheet-form cooling sheet 5 hereby has a larger surface area than the sheet-form carrier 1, in order to perform effectively as a cooling body. The surface area of the cooling body must indeed be greater than that of the carrier, to provide a large heat transfer surface.

The cooling sheet 5 is attached to the carrier opposite the components 4. This ensures that the thermal path through the ceramic carrier 1 is as short as possible.

It should be noted that the specific thermal resistance of the ceramic material from which the carrier 1 is produced is many times greater than that of the material with which the cooling sheet is attached.

This material is preferably copper. This is because copper not only has a low thermal resistance value, but also a high heat capacity. This heat capacity can be used to store heat during short-term loads that exceed the possible levels of heat dissipation under normal conditions.

The soldered connection 6 between the metal part 2 of the ceramic carrier 1 and the cooling sheet 5 ensures a significant reduction in thermal resistance compared with the usual configurations according to the prior art, such as the use of a thermally conductive paste.

The configuration shown in FIG. 1 is preferably used for circuits with a small number of components and small dimensions that can produce a large quantity of heat. Such circuits are applied in power control units, in particular for controlling the power of an electromotor, such as the electromotor of an electrical drilling machine, in particular but not exclusively if this machine is powered by a battery. It should be noted that the current strengths with devices powered by batteries are relatively high. This generates considerable heat in the components, so that the advantages of the invention are particularly apparent in this application.

Such a circuit is thus usually incorporated in a casing, together with other components of the circuit. It is important with such a configuration for the cooling sheet to be able to transfer its heat to the environment.

In this respect, FIG. 2 shows a situation in which an assembly of a carrier 1 with a cooling sheet 5 is incorporated in a casing 7 of a circuit. The cooling sheet extends to outside the casing through an opening 9 made in a wall 8 of the housing 7. This is advantageous in that a substantial part of the cooling surface of the cooling sheet 5 is located outside the housing 7. Indeed, the conditions are more favourable for the cooling process to take place outside the housing 7. With the cooling sheet 5 located partially outside the housing, it is also possible for the cooling sheet to be larger in design, so that the heat capacity can be increased, which is important for absorbing heat produced during intermittent operation.

With the embodiment shown in FIG. 2, it is difficult, if not impossible, to place the cooling sheet and carrier in the housing if they are already interconnected; it is easier to position both parts in the housing and then to connect them. To this end, the cooling sheet 5 is passed through an opening 9 made in the wall 8 of the housing 7, and then the carrier 1 is positioned on the part of the cooling sheet situated inside the housing. The assembly is then fixed using a hooked element 10. Both parts are then interconnected by means of a soldered connection, preferably a reflow soldered connection. It is however also possible to secure another metallic connection, for example a weld connection for example by means of laser welding or a metallic adhesive connection.

It should be noted that there are numerous other ways of implementing the features according to the invention.

1. Assembly of a carrier for electrical components that are arranged for producing more heat than can be dissipated via natural cooling at least under certain operating conditions and a cooling body mechanically and thermally connected thereto, characterised in that the carrier is provided with a metal part that is connected to the cooling body by means of a metallic connection.

2. Assembly according to claim 1, characterised in that the metallic connection is formed by a soldered connection.

3. Assembly according to claim 2, characterised in that the components are connected to the carrier by means of a soldered connection and that the melting temperature of the soldered connection between the components and the carrier is higher than the melting temperature of the soldered connection between the carrier and the cooling body.

4. Assembly according to claim 1, characterised in that the carrier is produced out of a ceramic material.

5. Assembly according to claim 1, characterised in that the metal part is a metal layer attached to the carrier by means of screen-printing.

6. Assembly according to claim 5, characterised in that the metal part of the carrier is mounted on the opposite side of the carrier that is supporting the components, directly opposite the components.

7. Assembly according to claim 1, characterised in that the cooling body is in sheet form.

8. Assembly according to claim 7, characterised in that the surface area of the sheet is greater than the surface area of the carrier.

9. Assembly according to claim 8, characterised in that the carrier is incorporated in a casing and that the cooling body extends inside as well as outside the casing.

10. Assembly according to claim 1, characterised in that the cooling body is at least as thick as the carrier.

11. Assembly according to claim 2, characterised in that the melting temperature of the soldered connection between the carrier and the cooling body is lower than the maximum temperature of the carrier occurring in short-term operation.

12. Method for assembling an assembly of a carrier for electrical components, at least one of which is arranged for producing more heat than can be dissipated via natural cooling at least under certain operating conditions, and a cooling body mechanically and thermally connected thereto, characterised in that the components are initially mounted on the carrier and a metal part of the carrier is then connected to the cooling body by means of a metallic connection.

13. Method according to claim 12, characterised in that the components are initially connected to the carrier by means of a soldered connection having a first melting point and in that the cooling body is then connected to the metallic part of the carrier by means of a soldered connection, whereby the melting point of the second soldered connection is lower than that of the first soldered connection.

14. Method according to claim 12, characterised in that once the components have been soldered, the carrier is positioned in a housing, in that the cooling body is then at least partially mounted in the housing and in that finally the soldered connection is secured between the cooling body and the metallic part of the carrier.

15. Method according to claim 12, characterised in that the soldered connection is formed by means of a reflow soldering process.

16. Switch unit, arranged for controlling the power of an energy converter connected to the switch unit, characterised by an assembly according to claim 1.

17. Electrical device, comprising an energy converter, characterised by a switch unit according to claim 16.

18. Electrical device according to claim 17, arranged for performing short-term operating cycles, characterised in that the heat capacity of the cooling body is dimensioned for absorbing the heat produced during an operating cycle by the components positioned on the carrier.

19. Electrical device according to claim 18, characterised in that the device is an electrical hand tool.

20. Electrical device according to claim 19, characterised in that the electrical device is a drilling or screwing machine.
